(19) United States
(12) Patent Application Publication
(10) Pub. No.: US 2016/0104073 A1
(43) Pub. Date: Apr. 14, 2016

(54) Radiation Suppression of Superconducting Quantum Bits Using a Conductive Plane

(71) Applicants: Martin Sandberg, Boulder, CO (US); Jiansong Gao, Boulder, CO (US); Michael Vissers, Erie, CO (US); David Pappas, Louisville, CO (US)

(72) Inventors: Martin Sandberg, Boulder, CO (US); Jiansong Gao, Boulder, CO (US); Michael Vissers, Erie, CO (US); David Pappas, Louisville, CO (US)

(73) Assignee: The United States of America as represented by the Secretary of Commerce, Gaithersburg, MD (US)

(21) Appl. No.: 14/097,809

(22) Filed: Dec. 5, 2013

Related U.S. Application Data
(60) Provisional application No. 61/733,449, filed on Dec. 5, 2012.

(51) Int. Cl. G06N 99/00; H01L 27/18; H01L 39/22; H01L 39/24; H01L 39/02; H01L 39/12

(52) U.S. Cl. CPC G06N 99/002; H01L 39/025; H01L 39/125; H01L 39/223; H01L 39/2416; H01L 39/2493; H01L 39/249; H01L 27/18

(57) ABSTRACT

This invention relates to a quantum computing device and the means for fabrication thereof. One side of the device includes a circuit containing at least one qubit patterned in a film of superconducting material. The other side of the device includes a conductive plane, also formed from a film of superconducting material. The proximity of the conductive plane suppresses radiative decay of the qubit, while readout is achieved by coupling the qubit to a resonator.

### STATEMENT OF GOVERNMENT INTEREST

The invention described herein was made by an employee of the United States Government and may be manufactured and used by the Government of the United States of America for governmental purposes without the payment of any royalties thereon or therefore.

### FIELD OF INVENTION

This invention relates to the field of superconducting quantum circuits, and more specifically to two-dimensional fabrication of a quantum circuit.

### BACKGROUND

A quantum bit, or qubit, is the smallest unit of information in a computer designed to manipulate or store information through effects predicted by quantum physics. Unlike binary digits, or bits, in classical systems, a qubit has more than two possible states: a state labeled 0, a state labeled 1, and a combination of the two states that obeys the superposition principle.

A quantum computer is a computation device that makes direct use of quantum-mechanical phenomena, such as superposition and entanglement, to perform operations on data. Quantum computers are different from digital computers based on transistor microprocessors. Digital computers require data to be encoded into bits, limiting them to one calculation at time. However, quantum computation uses quantum properties to represent data and perform multiple operations on these data at once.

Large-scale quantum computers will be able to perform many calculations simultaneously, as opposed to digital computers which can only perform one calculation at a time. Quantum computers will therefore be able to solve certain problems much faster than any digital computer using currently known algorithms, like integer factorization using Shor's algorithm or the simulation of quantum many-body systems. Quantum computers are also able to perform quantum algorithms, such as Simon's algorithm, which run faster than any possible probabilistic classical algorithm.

Some qubits known in the art are fabricated with coplanar capacitor pads connected by a non-linear inductive element. The capacitor pads create a dipole moment that will radiate, thereby dissipating the energy in the qubit in some characteristic time, T.

A problem known in the art with respect to this qubit structure is that the energy within the capacitor pads may prematurely dissipate before a calculation can be carried out. Presently, capacitor pads for qubits known in the art cannot maintain their charge for the duration required to perform a complex processing operation.

This problem of dissipation leads to computing errors. For example, a qubit which is intended to represent |1>value may prematurely drop to a |0>value. This can cause an error in the computation for which it is being used.

Many attempts have been made in the art to solve this problem. One solution is to fabricate a high quality factor three-dimensional cavity to house the qubit. The three-dimensional cavity is a metallic enclosure dimensionally designed to support only a few electromagnetic modes with very high quality factor. Quality factor is the resonant frequency of the modes divided by the linewidth of the modes. Typical quality factors of these cavities are greater than 1,000,000. The three-dimensional cavity acts to both suppress the radiative decay of the qubit and to measure the qubit state.

Several drawbacks exist to using three-dimensional cavities. Fabricating a three-dimensional cavity requires very pure superconducting materials with high precision machining and polishing by hand. Even though the cavities are very large (on the order of 1-2 cm in size), they can only hold a few qubits because the modes are highly spatially specific and the cavities have few locations where a qubit can be inserted. Finally, tuning and exciting the qubits in the cavity is challenging because the contacts required would degrade the quality factor and mode structure of the cavity. As a result, the three-dimensional technique is not scalable to allow for thousands of qubits to be integrated together.

It is desirable to extend the time period over which capacitors in a qubit can maintain their energy state.

It is also desirable to fabricate two-dimensional quantum circuits which can utilize qubits.

### SUMMARY OF THE INVENTION

This invention relates to a quantum computing device and the means for fabrication thereof. One side of the device includes a circuit containing at least one qubit patterned in a film of superconducting material. The other side of the device includes a conductive plane, also formed from a film of superconducting material. The proximity of the conductive plane suppresses radiative decay of the qubit, while readout is achieved by coupling the qubit to a resonator.

### TERMS OF ART

As used herein, the term “continuous superconducting ground plane” means a flat, unitary component which is connected to a ground and capable of becoming superconducting at sufficiently low temperatures.

As used herein, the term “double angle evaporation and oxidation” means the process of depositing a first metal layer in a pattern at a first angle, introducing oxygen to create an oxide layer, and then depositing a second metal layer in the pattern at a second angle.

As used herein, the term “electron-beam lithography” means emitting a beam of electrons in a patterned fashion across a surface covered with a film and selectively removing regions of the film.

As used herein, the term “hydrogen-terminated Si” means a chemically passivated silicon substrate whose native oxide (SiO₂) thin film is removed by etching in a hydrogen fluoride aqueous solution, leaving the surface silicon atoms covalently bonded to hydrogen.

As used herein, the term “Josephson junction interconnect” means a voltage-to-frequency converter sensitive to voltage, current and magnetic fields that is made of a superconducting wire interrupted by an insulating weak-link.

As used herein, the term “microstrip resonator” means a planar transmission line resonator with the conductor on the top of a chip and the ground plane on the bottom of the chip.

As used herein, the term “operational lifetime” means the time during which an element such as, but not limited to, a qubit can be used in a computational operation.

As used herein, the term “reactive ion etching” means using chemically reactive plasma to remove material.

As used herein, the term “reactive sputter deposition” means forming a deposited film by chemical reaction between the target material and a gas.

As used herein, the term “qubit” means a unit of quantum information; the quantum computing analogue of the classical computing bit.

As used herein, the term “resonator” means an electromagnetic device that naturally oscillates at some frequencies, called its resonant frequencies, with greater amplitude than at others.

As used herein, the term “transmon qubits” means a type of superconducting qubit that is designed to have reduced sensitivity to charge noise.

As used herein, the term “two-dimensional” means fabricated on the same surface.

### BRIEF DESCRIPTION OF THE DRAWINGS

FIG. 1 Illustrates an exemplary embodiment of a qubit chip fabricated with coplanar capacitor pads connected by a non-linear inductive element.

FIG. 2 illustrates an exemplary embodiment of a qubit chip apparatus with a conducting plane placed in close proximity to the qubit dipole to suppress the dipole radiation.

FIG. 3 illustrates a graphical representation of the relationship between the thickness of the chip substrate and qubit performance as measured in operational lifetime microseconds.

### DETAILED DESCRIPTION OF INVENTION

For the purpose of promoting an understanding of the present invention, references are made in the text to exemplary embodiments of a qubit chip and processes for fabricating such a chip, only some of which are described herein. It should be understood that no limitations on the scope of the invention are intended by describing these exemplary embodiments. One of ordinary skill in the art will readily appreciate that alternate but functionally equivalent components and steps may be used. The inclusion of additional elements may be deemed readily apparent and obvious to one of ordinary skill in the art. Specific elements disclosed herein are not to be interpreted as limiting, but rather as a basis for the claims and as a representative basis for teaching one of ordinary skill in the art to employ the present invention.

It should be understood that the drawings are not necessarily to scale; instead emphasis has been placed upon illustrating the principles of the invention. In addition, in the embodiments depicted herein, like reference numerals in the various drawings refer to identical or near identical structural elements.

Moreover, the terms “about” or “approximately” as used herein may be applied to modify any quantitative representation that could permissibly vary without resulting in a change in the basic function to which it is related.

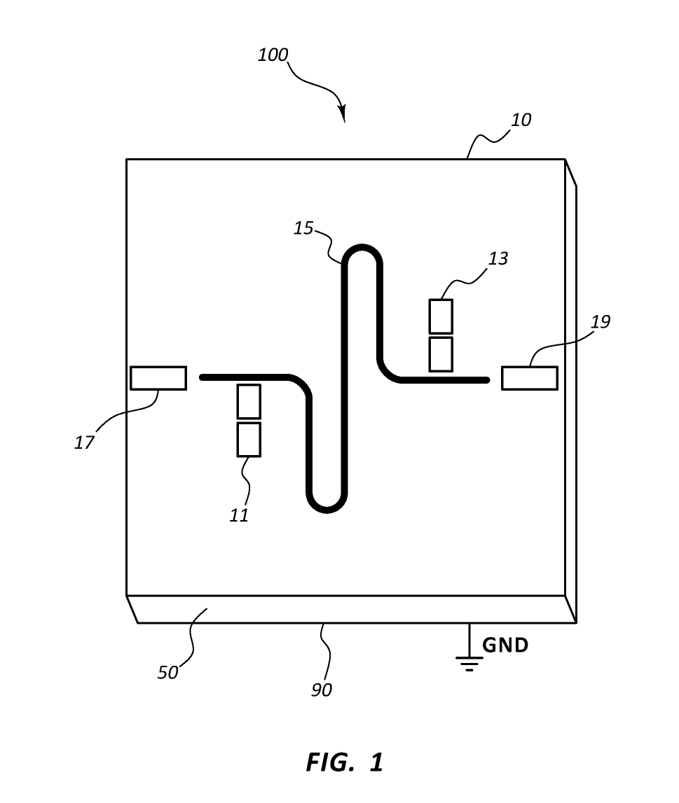

FIG. 1 is an exemplary embodiment of a qubit chip apparatus 100. In the exemplary embodiment, qubit chip apparatus 100 is fabricated with a two-dimensional circuit 10 located on a first substrate surface of a substrate 50. The second substrate surface of substrate 50 is attached to a continuous superconducting ground plane 90. Continuous superconducting ground plane 90 has a first planar surface operatively coupled to substrate 50 and a second planar surface.

Circuit 10 includes at least one qubit, shown in the exemplary embodiment as pair of qubits 11 and 13. Circuit 10 also includes at least one resonator 15 and a pair of ports 17 and 19. The ports are used to excite and probe the qubits by coupling microwaves to the qubits. In use, qubits 11 and 13 are operatively and capacitively coupled to resonator 15. Resonator 15 is used to read out qubits 11 and 13 during quantum computing operations. While resonator 15 is a microstrip resonator in the exemplary embodiment, other embodiments may use other types of resonators.

Each qubit 11 and 13 is structurally made up of at least one pair of capacitor pads connected by at least one non-linear inductive element, such as, but not limited to, the at least one Josephson junction interconnect of the exemplary embodiment. In this exemplary embodiment, materials selected must demonstrate the Josephson tunnel effect. While qubits 11 and 13 of the exemplary embodiment are transmon qubits, any other type of qubits can be used. The large capacitor pad structure of qubits 11 and 13 gives them a large dipole moment, allowing for strong coupling to microstrip 15. However, this also increases the radiation of the bare qubit, decreasing the operative lifetime T of qubits 11 and 13. The capacitor pads of qubits 11 and 13 may have at least one dimension ranging in size from about 0.1 micrometers to about 1000 micrometers.

The two-dimensional circuit 10 and continuous superconducting ground plane 90 of the exemplary embodiment of qubit chip apparatus 100 are fabricated primarily from first and second films of a superconducting material such as, but not limited to, titanium nitride (TiN), respectively, on an intrinsic silicon (Si) substrate. The very low microwave loss makes the TiN—Si system ideal for quantum circuits, as CPW resonators made from TiN on Si have internal quality factors greater than 1×10̂6 at single photon excitation. While the exemplary embodiment uses titanium nitride on silicon because of its low loss, alternate embodiments contemplate the use of any other combination of superconductor and dielectric.

A reactive sputter deposition process consecutively deposits the TiN films onto the first and second substrate surfaces of substrate 50. In the exemplary embodiment, substrate 50 is a dielectric material, such as, but not limited to, a Si wafer or a hydrogen terminated Si wafer. The TiN thereby forms continuous superconducting ground plane 90 and the basis for two-dimensional circuit 10. In the exemplary embodiment, photolithography techniques pattern microstrip resonator 15 and the capacitor pads for qubits 11 and 13 into the top film. In alternate embodiments, qubits can be designed on chips with no resonators and read out with proximal probes. Additional alternate embodiments couple the qubits directly to each other.

Fabrication of the structures of two-dimensional circuit 10 occurs in three steps. First, a highly controllable CF₄-based reactive ion etch (RIE) opens up a small area where at least one Josephson junction interconnect will be placed. In the second step, a SF₆-based RIE etches the remaining TiN of two-dimensional circuit 10 to form the resonator and capacitor pads. The second step is necessary because, while the SF₆ etch produces low loss Si surfaces, it also produces large trenches that are not suitable for the junction area due to a high etch rate (20:1) of Si:TiN in SF₆. In the third step, the Josephson junction interconnect between the capacitor pads is patterned with electron-beam lithography and formed by use of double angle evaporation and oxidation. This creates a metal-oxide-metal (MOM) structure of the Josephson junction interconnect. In an exemplary embodiment, the structure created is an aluminum/aluminum oxide/aluminum (Al/AlOx/Al) structure, with AlOx representing the amorphous form of aluminum oxide. This technique will work with qubits with any number of junctions that can be designed into this geometry.

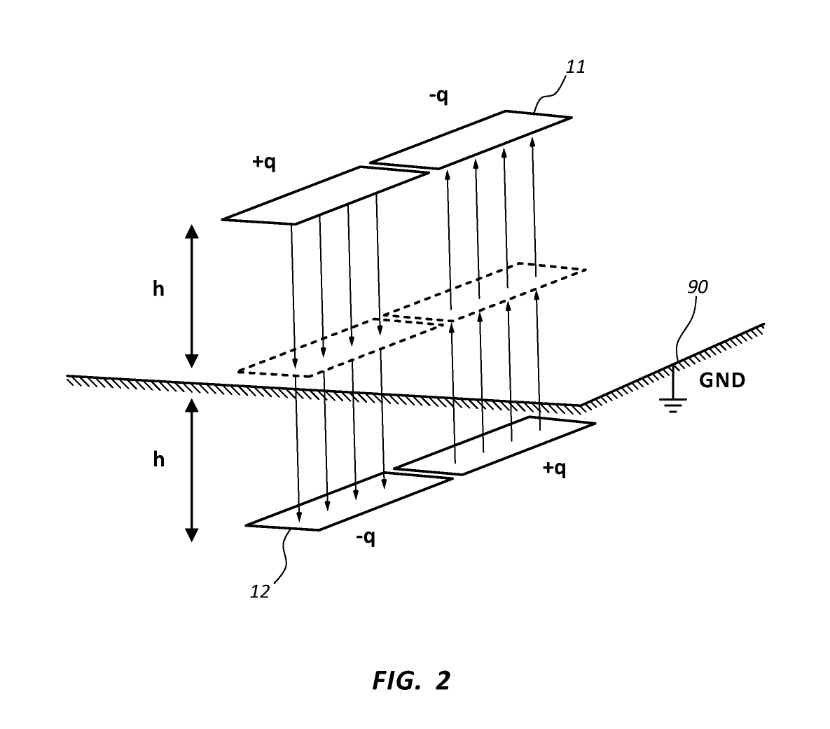

FIG. 2 illustrates an exemplary embodiment of qubit chip apparatus 100 with continuous superconducting ground plane 90 placed in close proximity to two-dimensional circuit 10, more specifically in close proximity to qubit 11. Distance h is the distance between qubits 11 and 13 and continuous superconducting ground plane 90. Distance h is selected according to the formula:

h<λ₀/4\sqrt{∈ᵣ}

where ∈ᵣ is relative permittivity of substrate 50 and λ₀ is a qubit wavelength in vacuum equal to f/c, where f is a frequency of the at least one qubit and c is the speed of light.

Since both two-dimensional circuit 10 and continuous superconducting ground plane 90 are respectively attached to a first substrate surface and a second substrate surface on either side of substrate 50, the thickness of substrate 50 is therefore approximately equal to h.

Continuous superconducting ground plane 90 generates a mirror image 12 of the qubit dipole that radiates approximately 180 degrees out of phase with the qubit dipole at distance h from continuous superconducting ground plane 90. The fields generated by the qubit 11 and the mirror image 12 act to cancel each other, suppressing the radiated power. A similar effect also generates a mirror image 14 (not shown) of opposite charge to qubit 13, suppressing the radiated power of qubit 13. These mirror images 12 and 14 thereby increase the operative lifetime T of qubit 11.

Continuous superconducting ground plane 90 also allows for elimination of discontinuous ground planes on the opposite side of the chip that can cause stray resonances.

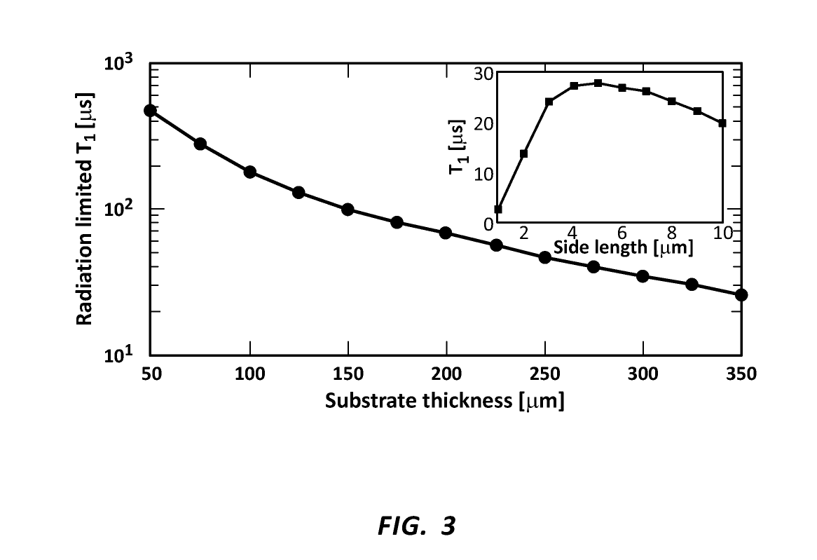

FIG. 3 illustrates a graphical representation of the calculated relationship between the thickness of the substrate and qubit performance as measured in operational lifetime microseconds. As shown, a thinner substrate results in increased operational lifetime T.

This is due to the ground plane acting to form a mirror dipole (as shown in FIG. 2) that is out of phase with the qubit. If the dipole is close to the conductive plane, the fields generated by the dipole itself and the fields generated by its mirror image will act to cancel each other. To estimate the effect of the ground plane a finite element solving algorithm may be used to calculate the outwards flowing power from the dipole with and without the ground. The lifetime of the qubit increases with decreasing distance to the conductive plane. The formula for this is:

$$P ∝ {( \frac{4 πh \sqrt{{ɛ}_{r}}}{{λ}_{0}} )}^{2}$$

where P̅ is the average power, h is the distance from the ground plane to the qubit, ∈ᵣ is the relative permittivity of the substrate and λ₀ is the qubit wavelength in vacuum, i.e. f/c where f is the frequency of the qubit and c is the speed of light. The numerical solution from the exact calculation for this is shown in FIG. 3.

For example, an experimental qubit with 250×400 micrometer pads was examined to determine its T on a 350 micrometer thick substrate with a continuous superconducting ground plane deposited on the second substrate surface. The theory predicted a 17 microsecond T in this geometry. The measured T of 12 microseconds was in quantitative agreement when coupling to the readout cavity was included.

In alternate embodiments, the qubit can be made using a lumped element cavity rather than a distributed element or by concentric coplanar electrodes connected via junction.

What is claimed is:

1. A device for use in a quantum computing system, comprising:
a substrate having a first substrate surface and a second substrate surface;
a two-dimensional circuit having at least one qubit and at least one resonator to which said at least one qubit is operatively coupled, wherein said two-dimensional circuit is formed from a superconducting material on said first substrate surface; and
a continuous superconducting ground plane located on said second substrate surface opposite from said two-dimensional circuit,
wherein said continuous superconducting ground plane is formed from a superconducting material,
wherein said continuous superconducting ground plane is positioned a distance h from said at least one qubit, wherein h<λ₀/4\sqrt{∈ᵣ} where ∈ᵣ is relative permittivity of said substrate and λ₀ is a qubit wavelength in vacuum equal to f/c, where f is a frequency of said at least one qubit and c is the speed of light.

2. The device of claim 1, wherein said at least one qubit is a transmon qubit.

3. The device of claim 1, wherein said continuous superconducting ground plane has a first planar surface and a second planar surface, wherein said first planar surface is operatively coupled to said second substrate surface.

4. The device of claim 3, wherein said substrate is a silicon (Si) wafer.

5. The device of claim 4, wherein said Si wafer is a hydrogen-terminated Si wafer.

6. The device of claim 1, wherein said two-dimensional circuit and said continuous superconducting ground plane are formed from titanium nitride (TiN).

7. The device of claim 1, wherein said at least one qubit is capacitively coupled to said resonator.

8. The device of claim 1, wherein said at least one qubit includes at least one pair of capacitor pads having at least one dimension ranging in size from about 0.1 micrometers to about 1000 micrometers.

9. The device of claim 8, wherein each of said at least one pair of capacitor pads includes at least one Josephson junction interconnect between each of said capacitor pads.

10. The device of claim 9, wherein each of said Josephson junction interconnects is made from a metal-oxide-metal (MOM) structure.

11. The device of claim 10, wherein said MOM structure is an aluminum/amorphous aluminum oxide/aluminum (Al/AlOx/Al) structure, wherein AlOx is an amorphous form of aluminum oxide.

12. The device of claim 1, wherein said at least one resonator is at least one microstrip resonator.

13. A method of making a device for use in a quantum computing system, comprising the steps of:
depositing a first titanium nitride (TiN) film on a first substrate surface of a silicon (Si) substrate and depositing a second TiN film on a second substrate surface of said Si substrate, wherein said first substrate surface and said second substrate surface are opposing surfaces a distance h from each other, wherein h<λ₀/4\sqrt{∈ᵣ} where ∈ᵣ is relative permittivity of said Si substrate and λ₀ is a qubit wavelength in vacuum equal to f/c, where f is a frequency of at least one qubit and c is the speed of light;
patterning said first TiN film to create patterns for at least one pair of capacitor pads and at least one microstrip resonator; and
forming at least one Josephson junction interconnect between said at least one pair of capacitor pads to form said at least one qubit.

14. The method of claim 13, wherein said first TiN film and said second TiN film are deposited on said first substrate surface and said second substrate surface of said Si substrate, respectively, using a reactive sputter deposition process.

15. The method of claim 13, wherein said at least one microstrip resonator and said at least one pair of capacitor pads are patterned using a photolithography process.

16. The method of claim 13, wherein said at least one microstrip resonator and said at least one pair of capacitor pads are formed using a reactive ion etching (RIE) process.

17. The method of claim 16, wherein said RIE process is a sulfur-hexafluoride (SF₆) based RIE.

18. The method of claim 13, wherein an area for said at least one Josephson junction interconnect is opened using a RIE process.

19. The method of claim 13, wherein said at least one Josephson junction interconnect is patterned using an electron-beam lithography process.

20. The method of claim 13, wherein said at least one Josephson junction interconnect is formed using a double angle evaporation and oxidation process.
